(19) United States
(12) Patent Application Publication
(10) Pub. No.: US 2003/0053330 A1
(43) Pub. Date: Mar. 20, 2003

(54) Dual capacitor dynamic random access memory cell

(75) Inventors: Jeng-Jye Shau, Palo Alto, CA (US); Byeong-Cheal Na, Pleasanton, CA (US)

Correspondence Address: Bo-In Lin, 13445 Mandoli Drive, Los Altos Hills, CA, 94022, US

(73) Assignee: UniRAM Technology, Inc.

(21) Appl. No.: 10/167,383

(22) Filed: Jun. 10, 2002

Related U.S. Application Data
(60) Provisional application No. 60/322,477, filed on Sep. 13, 2001.

(51) Int. Cl. G11C 11/24

(52) U.S. Cl. 365/149

(57) ABSTRACT

This invention discloses a dynamic random access memory (DRAM) memory cell. The DRAM memory cell includes a first transistor-capacitor circuit connected to a first bitline BL and a second transistor-capacitor circuit connected to a second bitline BL#. The memory cell further includes a gate of the first transistor connected to a gate of the second transistor. The DRAM cell further includes a sense amplifier connected to the first bit line BL and the second bit line BL# for measuring a binary bit from sensing a voltage difference between the first and second transistor-capacitor circuits independent from a pre-charged bit-line voltage.

This is a Formal Application of a Provisional Application 60/322,477 filed on Sep. 13, 2001. The Provisional Patent Application 60/322,477 is a Continuous-In-Part (CIP) Application of a previously filed co-pending Application with Ser. No. 08/653,620 filed on May 24, 1996 and another co-pending application Ser. No. 08/805,290 filed on Feb. 25, 1997 and another co-pending application Ser. No. 09/753,635 filed on Jan. 2, 2001 by one of the inventors for this Formal CIP Application.

### BACKGROUND OF THE INVENTION

1. Field of the Invention

The present invention relates to high-performance semiconductor memory devices. More particularly, this invention is related to dynamic random access memory (DRAM) specially configured for storing a binary bit in dual capacitors to achieve higher data accessing speed, reduction of refresh requirement and standby currents, and increasing the production yields.

2. Description of the Prior Art

Even that the dynamic random access memory (DRAM) device provides the advantages of high density and low cost, a DRAM device is limited in its usefulness due to a higher production yield requirement and the refresh operations to maintain the electric charges stored in a capacitor in each DRAM cell. This refresh requirement causes a standby power to increase and that leads to technical difficulties to implement the conventional DRAM device in embedded applications.

Two major types of volatile memory devices are dynamic random access memory (DRAM) and static random access memory (SRAM). Each devices has its unique structural and functional characteristics. Compared to DRAM, SRAM device has the advantages of high speed and low power. On the other hand, even with a lower level of performance in terms of speed and power, DRAM devices has several advantages over SRAM as DRAM is considered as a high density, low cost device. In the mean time, the density of DRAM cells has been improved rapidly; the extent of integration has been more than doubled for every generation. Such higher integration of DRAM has been realized mainly by super fine processing technique and improvements in memory cell structure. Therefore, for cost sensitive and high-density operations, DRAM devices are widely used. The high density structural characteristic of the DRAM cells is achieved by its simple structure as a conventional DRAM cell includes only one transistor and one capacitor for electric charge storage. As discussed above, due to a gradual loss of electrical charges from the capacitor in each DRAM cell, a refresh operation is necessary even a memory cell is not activated for a read or a write operation. A critical factor that dictates the elapse time between two refresh operations is the bitline pair voltage difference after a “charge sharing” operation. A sense amplifier senses this bitline pair voltage difference to develop from this sensed voltage difference to a full VDD or VSS to write back to the cell to maintain the state of the binary data bit stored in each cell after completion of a refresh operation. When a charge loss from the capacitor in a DRAM cell causes the bitline voltage difference to drop below a certain level and the sense amplifier is not able to correctly determine the bitline voltage difference. And, this inability of the sense amplifier to correctly sense the bitline voltage difference causes a failure to read the data in a memory cell.

Referring to FIGS. 1 and 2 for a conventional DRAM device and cell structure respectively. As shown in FIG. 1, each DRAM cell in a memory array is connected to a bitline pair, e.g., bitline BL and a second bitline BL# while the transistor of each memory cell is placed on one side of a word-line. The charge sharing operation occurs only at one bitline, either BL or BL# while the other bitline stays at a pre-charge voltage level before a sensing operation of the sensing amplifier begins. Due to this non-symmetrical charge sharing action among the BL/BL# bitline pairs, the bitline voltage difference •VBL depends on a pre-charge voltage level. Referring to FIG. 2 now for a more specific description of this operation that is related to a basic relationship between the electric charges Q and the capacitance C:

Q=VC (1)

And, the bitline voltage VBL after a word line is turned on can be expressed as:

VBL=(CBVPC+CSVS)/(CB+Cs) (2)

Where VPC=pre-charge voltage of bitline, CB is the bitline capacitance, CS is the cell capacitance of the cell capacitor, and VS is the voltage of the storage node. If the voltage of the storage node VS is the same as the pre-charge voltage VPC, then:

VBL=VPC+(VS−VPC)/[(CB/Cs)+1)] (3)

The bitline voltage difference •VBL can then be calculated as:

$$\begin{matrix}Δ V B L = V B L - V B L \# = V B L - V P C \\ = ( V S - V P C ) / [ ( C B / C s ) + 1 ) ]\end{matrix} \qquad ( 4 )$$

When the a binary data is one, and Vs=VDD and VPC is set at half of VDD then

ΔVBL=(½)VDD/[(CB/Cs)+1)] (5)

When the a binary data is zero, and Vs=0, and VPC is set at half of VDD then

VBL=−(½)VDD/[(CB/Cs)+1)] (6)

For these reasons, the pre-charge voltage VPC is set at half of VDD in order to make the bitline voltage difference at about a same magnitude for both the high and low binary data bit. FIGS. 3 and 4 show the variation of the bitline voltages VBL and VBL# when the data binary is either one or zero. Since there is a limit in sensing the bitline voltage difference by the sense amplifier because when the value of •VBL drops below certain sensing threshold, a read failure would occur. It is required to keep the bitline voltage difference above the sensing threshold. In order to prevent the read failure problems, many DRAM designs are intended to maximize the stored charges in the capacitor in each DRAM cell. According to a Q=CV relationship where Q is the electrical charges, C is the capacitance and V is voltage across the capacitor, the electric charges Q can be increased by either increasing the capacitance C of the voltage V. Under the circumstances that the sense amplifier remains unchanged, the refresh requirements can be relaxed by increasing Q with increased C or V. However, in a high density DRAM device, it is generally not desirable to increase the capacitance due to the adverse effects of reduce the cell density with larger capacitors provided for each memory cell. Use a higher standby power to increase the voltage V is the design process generally implemented to improve the refresh frequency requirements. With an increased standby power requirement, the usefulness of the DRAM device for embedded system is significantly reduced.

Furthermore, due to the non-symmetrical nature of the cell structure, the voltage waveforms for sensing the high and low binary bits are different. For the purpose of sensing the high binary bits, it is necessary to apply a voltage to the word-line higher than the voltage VDD in order to transfer the high binary bits because the N-channel transistors are generally employed as the cell transistor. The DRAM design often requires a boost voltage source to the word-line enabling operation and this extra voltage boost requirement causes further complication in design and operations when implementing the DRAM memory device.

Therefore, a need still exits in the art of DRAM device design and manufacture to provide an effective method and configuration to resolve this limitations. It is desirable that a new method and configuration can be conveniently implemented without significant changing the processes of design and manufacture such that the advantages of simple structure, low cost and high density can be maintained.

### SUMMARY OF THE PRESENT INVENTION

The primary objective of this invention is, therefore, to provide new circuit configuration and method to design and operate a DRAM device. Specifically, a DRAM memory device that includes DRAM cell having symmetrical dual capacitors is disclosed. The memory cells of this configuration require less frequent refresh operations thus requiring reduced standby current. The dual-capacitor memory cell provides higher speed of memory cell access because increased bitline voltage differences. The memory device further allows more flexibility to adjust the pre-charge voltage. Furthermore, because there are dual capacitors in each memory cells, one of the dual capacitors is available as a backup storage node in case one of the dual capacitors does not function properly. The production yield of the DRAM device is increased because of a fault tolerant nature of the configuration with dual capacitors disclosed in this invention.

While the novel features of the invention are set forth with particularly in the appended claims, the invention, both as to organization and content, will be better understood and appreciated, along with other objects and features thereof, from the following detailed description taken in conjunction with the drawing.

### BRIEF DESCRIPTION OF THE DRAWINGS

FIG. 1 is a schematic block diagram of a prior art DRAM memory device;

FIG. 2 is a circuit diagrams of a prior art DRAM memory cell;

FIGS. 3 and 4 are diagrams for showing variations of bitline voltage changes for a high and low data binary bit stored in a memory cell;

FIG. 5 is a schematic block diagram of a DRAM memory device; of this invention

FIG. 6 is a circuit diagrams of a new DRAM memory cell of this invention; and

FIGS. 7 and 8 are diagrams for showing variations of bitline voltage changes for a high and low data binary bit stored in a memory cell implemented with dual-capacitor memory cells.

### DETAILED DESCRIPTION OF THE INVENTION

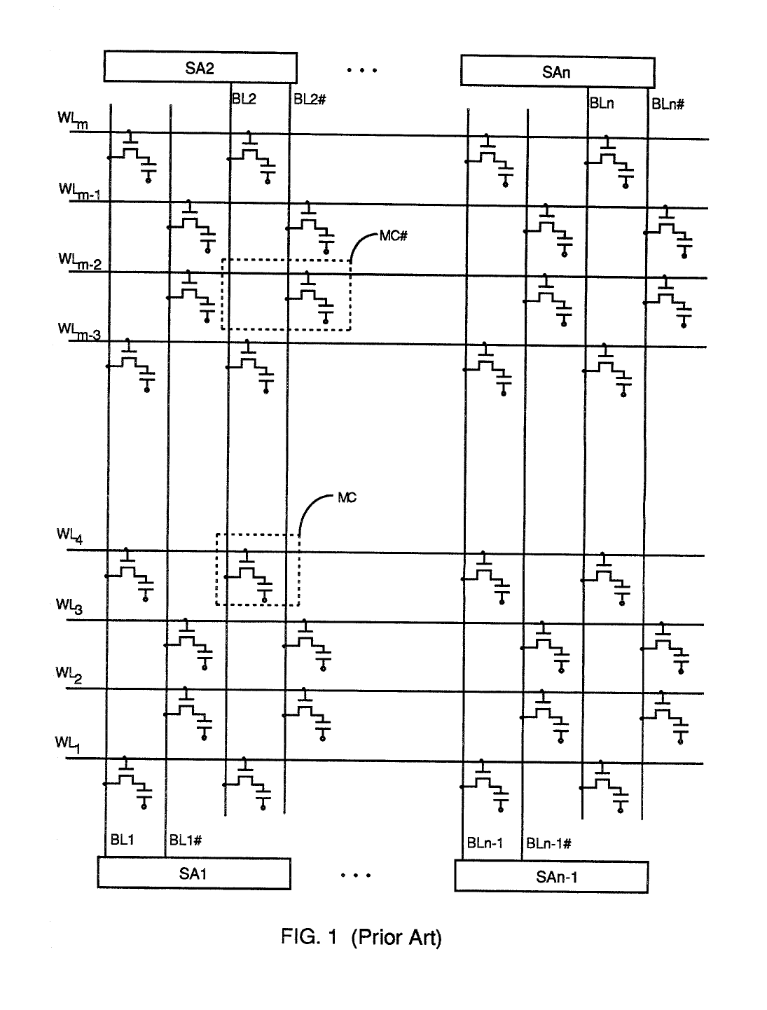

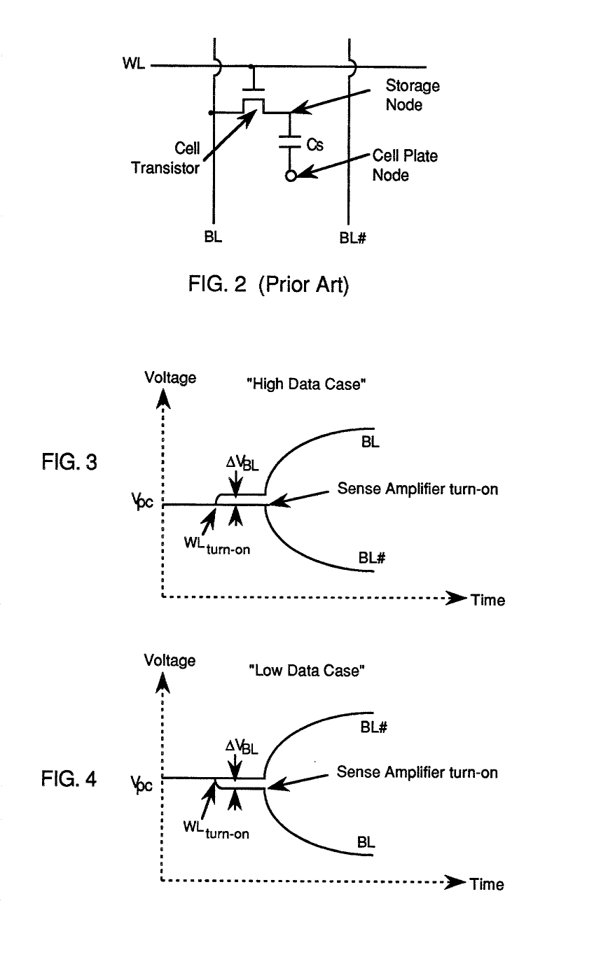

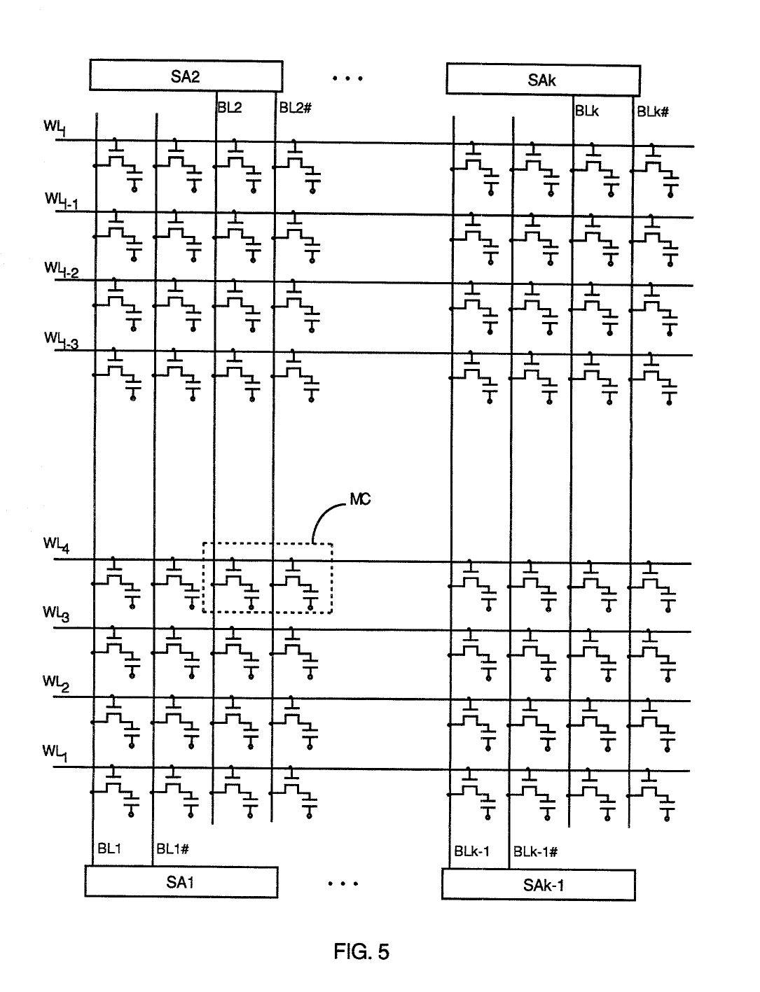

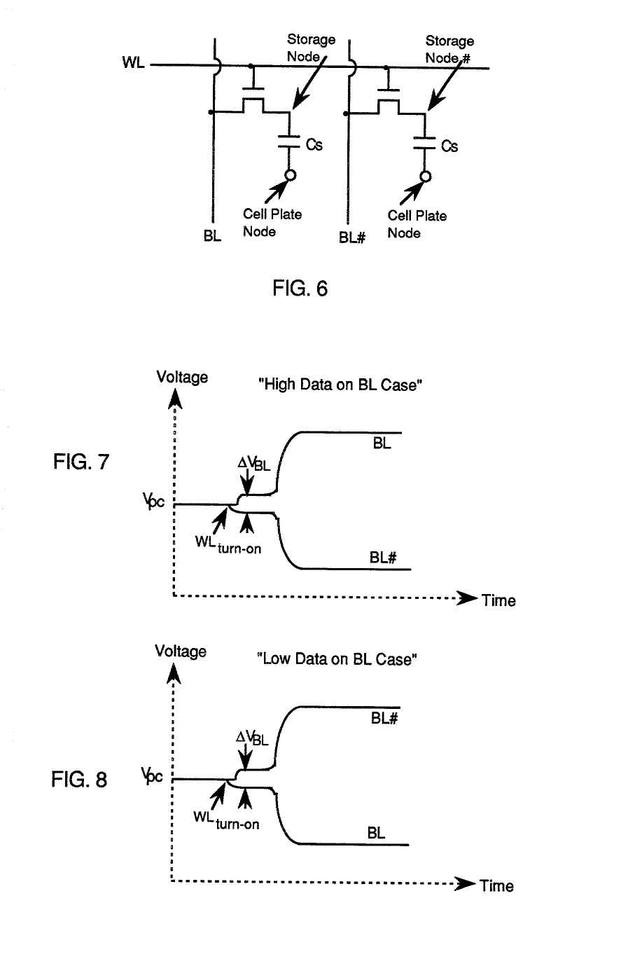

Referring to FIGS. 5 for a new configuration of a DRAM memory device and memory cell respectively of this invention. Instead of employing a single capacitor for storing a binary bit as that shown in FIGS. 1 and 2, the new DRAM memory cell of this invention stores a bit using dual capacitors with symmetrical configuration. Referring to FIG. 6 now for a more specific description of the configuration and operation of a dual capacitors memory cell. Based on the relationship of Q=VC, the bitline voltage VBL after a word line is turned on can be expressed as:

VBL=VPC+(VS−VPC)/[(CB/Cs)+1)] (7)

And

VBL#=VPC+(VS#−VPC)/[(CB/Cs)+1)] (8)

Where VPC=pre-charge voltage of bitline, CB is the bitline capacitance, CS is the cell capacitance of the cell capacitor, and VS is the voltage of the storage node connected to bitline BL and VS# is the voltage of the storage node connected to bitline BL#. The bitline voltage difference ΔVBL can then be calculated as:

$$\begin{matrix}Δ V B L = V B L - V B L \# = ( V S - V S \# ) / [ ( C B / C s ) + 1 ) ] \\ = Δ V S / [ ( C B / C s ) + 1 ) ]\end{matrix} \qquad ( 9 )$$

When the a binary data is one, and Vs=VDD and Vs#=Vss=0, the bitline voltage difference is:

ΔVBL=(VS−VS#)/[(CB/Cs)+1)]=VDD/[(CB/Cs)+1)] (10)

From above equations, the bitline pair now has voltage difference that is doubled in value than that of the single capacitor cell. The elapsed time between the refresh operations can be significantly increased since the concerns for a read error due to the bitline voltage difference drops below a sensing threshold voltage is now decreased. The standby current can be reduced with less refresh requirement. The access time to the memory cells is decreased because the greater value of bitline voltage difference and faster sensing is now achieved. Higher speed of data read/write operations can be achieved. Referring to FIGS. 7 and 8, the bitline voltage difference ΔVBL is no longer depends on the pre-charge voltage level but is now defined by the voltage difference between the voltage levels of the dual storage nodes. With this VPC independent operation characteristics, the DRAM memory device is provided with significant degree of freedom to flexibly adjust the pre-charge voltage depending on other design considerations.

Since there are two sets of transistor-capacitor unit in each memory cell for binary bit storage, under the circumstance where one of these two sets has a weak performance, the other 1T/1C set is still available for storing a binary bit. Therefore, one of the dual transistor-capacitor sets is available as a backup data-storage unit under the circumstances that one of the dual transistor-capacitor sets is not functioning properly either due to manufacture defects or damaged during operations. The new DRAM cell configuration according to this invention with dual transistor-capacitor operation units therefore provides an advantageous fault tolerant feature to improve the production yield using the same process technology. Furthermore, as the requirements for word-line boost voltage are eliminated, the design and manufacture of a DRAM device are simplified. Improvements in production yield can be achieved with simplified processing steps for a DRAM device of this invention. Because of the lower standby power, fast data access and high production yield, a DRAM memory cell provided with dual transistor-capacitor operation units as disclosed in the present invention is more suitable for embedded applications.

According to FIGS. 5 to 8 and above descriptions, this invention discloses a method for configuring a dynamic random access memory (DRAM) memory cell. The method includes steps of A) connecting a first transistor-capacitor circuit to a first bitline BL and connecting a second transistor-capacitor circuit to a second bitline BL#. And, B) connecting a gate of the first transistor to a gate of second transistor.

This invention further discloses a dynamic random access memory (DRAM) memory cell. The DRAM memory cell includes a first transistor-capacitor circuit connected to a first bitline BL and a second transistor-capacitor circuit connected to a second bitline BL#. The memory cell further includes a gate of the first transistor connected to a gate of the second transistor.

In essence this invention discloses a method for configuring a memory cell. The method includes a step of connecting a first and a second capacitors to a sensing means provided for sensing electromagnetic characteristics of the capacitors. This invention further discloses a memory cell that includes a first and a second capacitors connected to a sensing means provided for sensing electromagnetic characteristics of the capacitors.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A method for configuring a dynamic random access memory (DRAM) memory cell comprising:
connecting a first circuit having a first transistor and a first capacitor to a first bitline BL and connecting a second circuit having a second transistor and second capacitor to a second bitline BL#;
connecting a gate of said first transistor to a gate of second transistor; and
connecting said first bit line BL and said second bit line BL# to a sense amplifier for measuring a binary bit from sensing a voltage difference between said first and second capacitor independent from a pre-charged bit-line voltage.

2. The method of claim 1 further comprising:
connecting said gate of said first transistor and said gate of said second transistor to a wordline WL.

3. A method for configuring a DRAM memory cell comprising:
forming two capacitors symmetrically disposed in said DRAM cell for storing electrical charges therein and detecting a binary bit based on a voltage difference between said two capacitors.

4. The method of claim 3 further comprising:
connecting a first transistor to said first capacitor for forming a first transistor capacitor circuit and connecting a second transistor to said second capacitor for forming a second transistor-capacitor circuit.

5. The method of claim 4 further comprising:
connecting said first transistor capacitor circuit to a first bitline BL and connecting said second transistor-capacitor circuit to a second bitline BL#; and
connecting a gate of said first transistor to a gate of second transistor.

6. The method of claim 5 further comprising:
connecting said first bit line BL and said second bit line BL# to a sense amplifier for detecting said voltage difference independent of a pre-charged voltage to one of said first and second bit-lines.

7. The method of claim 6 further comprising:
connecting said gate of said first transistor and said gate of said second transistor to a wordline WL.

8. A dynamic random access memory (DRAM) memory cell comprising:
a first circuit having a first transistor and a first capacitor connected to a first bitline BL and a second circuit having a second transistor and a second capacitor connected to a second bitline BL#; and
a gate of said first transistor connected to a gate of said second transistor
a sense amplifier connected to said first bit line BL and said second bit line BL# for measuring a binary bit from sensing a voltage difference between said first and second capacitors independent from a pre-charged bit-line voltage.

9. The DRAM cell of claim 7 further comprising:
a wordline WL connected to said gate of said first transistor and said gate of said second transistor.

10. A DRAM memory cell comprising:
two capacitors symmetrically disposed in said DRAM cell for storing electrical charges therein and for detecting a binary bit based on a voltage difference between said two capacitors.

11. The DRAM memory cell claim 10 further comprising:
a first transistor connected to said first capacitor constituting a first transistor-capacitor circuit and a second transistor connected to said second capacitor constituting a second transistor-capacitor circuit.

12. The DRAM memory cell of claim 11 further comprising:
a first bitline connected to said first transistor-capacitor circuit and a second bitline connected to said second transistor-capacitor circuit; and
a gate of said first transistor connected to a gate of second transistor.

13. The DRAM memory cell of claim 14 further comprising:
a sense amplifier connected to said first bit line BL and said second bit line BL# for detecting said voltage difference independent of a pre-charged voltage to one of said first and second bit-lines.

14. The DRAM memory cell of claim 12 further comprising:
a wordline connected to said gate of said first transistor and said gate of said second transistor.

15. A method for configuring a memory cell comprising:
connecting a first and a second capacitors to a sensing means provided for sensing a difference of electromagnetic characteristics between said capacitors.

16. The method of claim 15 further comprising:
connecting a first and second transistors each to one of said two capacitors to form a first and second transistor-capacitor circuits symmetrically disposed in said memory cell for storing electrical charges therein for detecting a binary bit based on a voltage difference between said two capacitors.

17. The method of claim 16 further comprising:
connecting said first transistor capacitor circuit to a first bitline BL and connecting said second transistor-capacitor circuit to a second bitline BL#; and
connecting a gate of said first transistor to a gate of second transistor.

18. The method of claim 17 further comprising:
connecting said first bit line BL and said second bit line BL# to a sense amplifier for detecting said voltage difference independent of a pre-charged voltage to one of said first and second bit-lines.

19. The method of claim 17 further comprising:
connecting said gate of said first transistor and said gate of said second transistor to a wordline WL.

20. A memory cell comprising:
a first and a second capacitors connected to a sensing means provided for sensing a difference of electromagnetic characteristics between said capacitors.

21. A memory device comprising a plurality of memory cells wherein each of said memory cells further comprising:
a first and a second capacitors connected to a sensing means provided for sensing a difference of electromagnetic characteristics between said capacitors for detecting a data bit stored in said memory cell.
